(19) United States
(12) Patent Application Publication
(10) Pub. No.: US 2009/0161410 A1
(43) Pub. Date: Jun. 25, 2009

(54) SEVEN TRANSISTOR SRAM CELL

(75) Inventor: Theodore W. Houston, Richardson, TX (US)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/962,713

(22) Filed: Dec. 21, 2007

(51) Int. Cl. G11C 11/00; G11C 7/00

(52) U.S. Cl. 365/154; 365/189.14

(57) ABSTRACT

The present disclosure provides a seven transistor static random access memory (7T SRAM) cell. In one embodiment, the 7T SRAM cell includes a pair of cross-coupled inverters configured to provide a memory element having first and second storage nodes. The 7T SRAM cell also includes a Read isolation transistor having a control element connected to one of the storage nodes of the cross-coupled transistor inverters and configured to provide a buffered Read output. The 7T SRAM cell further includes a Read pass gate transistor controlled by a Read word line and connected between the Read isolation transistor and a read bit line. Additionally, the 7T SRAM cell still further includes a Write pass gate transistor controlled by a Write word line and connected between one of the storage nodes of the cross-coupled inverters and a Write bit line to write either state of the memory element.

### TECHNICAL FIELD OF THE INVENTION

The present invention is directed, in general, to a static random access memory (SRAM) and, more specifically, to a seven transistor SRAM employing both single-sided writing and buffered, single-sided reading capabilities.

### BACKGROUND OF THE INVENTION

A typical SRAM device is designed to store many thousands of bits of information. These bits are stored in individual cells, organized as rows and columns to make efficient use of space on a semiconductor substrate containing the SRAM device. A commonly used cell architecture is known as the “6T” cell, by virtue of having six MOS transistors. Four transistors defining an SRAM cell core or memory element are configured as cross-coupled CMOS inverters, which act as a bistable circuit that indefinitely holds the state imposed onto it while powered. Each CMOS inverter includes a load or “pull-up” transistor and a driver or “pull-down” transistor. The output of the two inverters will be in opposite states, except during transitions from one state to another. Two additional transistors are known as “pass gate” transistors, which provide access to the cross-coupled inverters during a read operation (herein referred to as READ) or write operation (herein referred to as WRITE). The gate inputs of the pass transistors are typically connected in common to a “word line” or WL. The drain of one pass gate transistor is connected to a “bit line” or BL, while the drain of the other pass gate transistor is connected to the logical complement of the bit line, or BL_.

A WRITE to a 6T cell is effected by asserting a desired value on the BL, a complement of that value on BL_, and asserting the WL. Thus, the prior state of the cross-coupled inverters is overwritten with a current value. A READ is effected by first precharging both bit lines to a logical high state and then asserting the WL. In this case, the output of one of the inverters in the SRAM cell will pull one bit line lower than its precharged value. A sense amplifier detects the differential voltage on the bit lines to produce a logical “one” or “zero” depending on the internally stored state of the SRAM cell.

A consideration in the design of the transistors in the SRAM cell is the geometric parameters of the transistors. The gate length and width determine, in large part, the speed and saturation drive current, I_{Dsat}, also known as the maximum drive current, capacity of the transistors. Appropriate values of gate length and width of the six transistors of the 6T cell are chosen to ensure that a read operation does not destroy the previously stored datum. Inappropriate transistor parameter values in conjunction with the BL and WL voltages applied during a READ may result in an unwanted change in state of the memory cell due to random asymmetries caused by imperfections in the manufacturing process. The necessity to guard against such READ instability places an undesirable constraint on the design parameters of the transistors in the 6T SRAM cell. This constraint limits the ability of a designer to increase READ performance of the SRAM while keeping within area and power constraints and concurrently maintain the ability to write into the cell.

Additionally, with scaling, it is becoming increasingly difficult to design a 6T SRAM cell that has adequate static noise margin (SNM), robustness for WRITE (Vₜᵣᵢₚ), good read current (I_{read}), low leakage current (I_{DDQ}) and small area. One way of overcoming some of these limitations is to add transistors that buffer the 6T SRAM cell during the READ operation. Some cells add two transistors to provide a buffered READ thereby making the 6T SRAM cell into an 8T SRAM cell. This appreciably increases the layout real estate and the power required for the SRAM cell, thereby reducing the overall benefit.

Accordingly, what is needed in the art is a more efficient and effective way to overcome the limitations afforded by present SRAM cells.

### SUMMARY OF THE INVENTION

Embodiments of the present disclosure provide a seven transistor static random access memory (7T SRAM) cell, a method of operating the 7T SRAM cell and an integrated circuit employing the 7T SRAM cell. In one embodiment, the 7T SRAM cell includes a pair of cross-coupled inverters configured to provide a memory element having first and second storage nodes. The 7T SRAM cell also includes a Read isolation transistor having a control element connected to one of the storage nodes of the cross-coupled transistor inverters and configured to provide a buffered Read output from the memory element. The 7T SRAM cell further includes a Read pass gate transistor controlled by a Read word line and connected between the Read isolation transistor and a read bit line to read the buffered Read output. Additionally, the 7T SRAM cell still further includes a Write pass gate transistor controlled by a Write word line and connected between one of the storage nodes of the cross-coupled inverters and a Write bit line to write either state of the memory element.

The present disclosure also provides, in another aspect, a method of operating a 7T SRAM cell. The method includes providing a memory element with a pair of cross-coupled inverters having first and second storage nodes. The method also includes writing a memory state of the memory element from a Write bit line to one of the first and second storage nodes through a Write pass gate transistor controlled by a Write word line. The method further includes reading the memory state to a Read bit line through a control element of a Read isolation transistor connected between one of the first and second storage nodes and a Read pass gate transistor controlled by a Read word line.

The present disclosure also provides, in yet another aspect, an integrated circuit. The integrated circuit includes a Read word line and a Write word line corresponding to each row of a static random access memory (SRAM) array, and a Read bit line and a Write bit line corresponding to each column of the SRAM array. The integrated circuit also includes a seven transistor SRAM (7T SRAM) cell corresponding to a bit position at each intersecting row and column. The 7T SRAM cell has a pair of cross-coupled inverters with first and second storage nodes, a Read isolation transistor having a control element that is connected to one of the storage nodes of the cross-coupled inverters and a Read pass gate transistor that is controlled by the Read word line of the bit position and connected between the Read isolation transistor and the Read bit line of the bit position. The 7T SRAM cell also has a Write pass gate transistor that is controlled by the Write word line of the bit position and connected between one of the storage nodes of the cross-coupled inverters and the Write bit line of the bit position.

### BRIEF DESCRIPTION OF THE DRAWINGS

For a more complete understanding of the present invention, reference is now made to the following descriptions taken in conjunction with the accompanying drawings, in which:

FIG. 1A illustrates an integrated circuit including an SRAM array as provided by one embodiment of the disclosure;

FIG. 1B provides a timing diagram showing writing and reading a ONE and a ZERO for the SRAM array of FIG. 1A;

FIG. 2 illustrates an embodiment of a 7T SRAM cell as may be employed in the SRAM array of FIG. 1A;

FIG. 3 illustrates an extension of one embodiment of the 7T SRAM cell of FIG. 2 to provide a 9T SRAM cell having differential READ capability;

FIG. 4A illustrates an integrated circuit including an SRAM array as provided by an alternative embodiment of the disclosure;

FIG. 4B provides a timing diagram showing writing and reading a ONE and a ZERO for the SRAM array of FIG. 4A;

FIG. 4C provides an alternative timing diagram where supply voltage write assist is employed for the SRAM array of FIG. 4A;

FIG. 4D provides yet another timing diagram where overdrive of the Write bit line is employed for the SRAM array of FIG. 4A;

FIG. 5 illustrates an embodiment of a 7T SRAM cell as may be employed in the SRAM array of FIG. 4;

FIG. 6A shows an example of a physical layout for the 7T SRAM cell of FIG. 2 for the connection represented by node A;

FIG. 6B shows an arrangement of neighboring physical layouts on a substrate corresponding to the physical layout of FIG. 6A;

FIG. 7A shows an example of a physical layout of the 7T SRAM cell of FIG. 5 for the connection represented by node B; and

FIG. 7B shows an arrangement of neighboring physical layouts on a substrate corresponding to the physical layout of FIG. 7A.

FIG. 8 shows a flow diagram of an embodiment of a method of operating a 7T SRAM cell carried out according to the principles of the present disclosure.

### DETAILED DESCRIPTION

The present disclosure provides embodiments of a 7T SRAM cell that may be employed to mitigate at least a portion of the problems associated with scaling to smaller geometries. The 7T SRAM cell employs a single-sided WRITE and a single-sided READ, wherein the single sided READ uses a gain cell type output. In addition to providing a smaller footprint area than an 8T SRAM cell, this configuration maintains an adequate static noise margin (SNM) as well as provides robustness for WRITE (Vₜᵣᵢₚ), good read current capabilities (I_{read}) and low leakage current (I_{DDQ}).

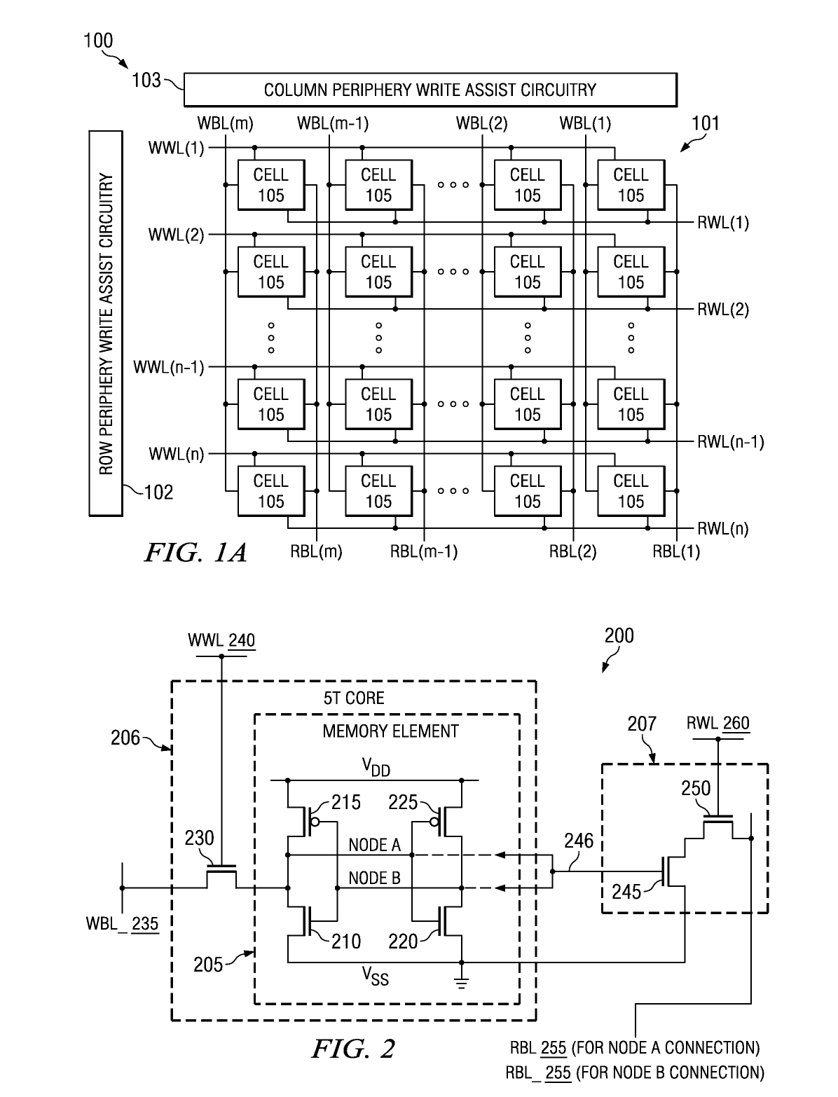

FIG. 1A illustrates an integrated circuit 100 including an SRAM array 101 as provided by one embodiment of the disclosure. The SRAM array 101 is shown having memory cells 105 wherein each cell is a 7T SRAM cell employing single and separate Write and Read word lines as well as single and separate Write and Read bit lines. The SRAM array 101 includes a plurality of Write word lines WWL(1)-WWL(n) and corresponding Read word lines RWL(1)-RWL(n) associated with n rows of memory cells. The SRAM array 101 also includes a plurality of Write bit lines WBL(1)-WBL(m) and a plurality of Read bit lines RBL(1)-RBL(m) associated with m columns of memory cells. Each of the 7T SRAM cells employs corresponding Write word and bit lines and Read word and bit lines to provide a single-sided WRITE and a buffered, single-sided READ from each memory cell 105. The integrated circuit 100 further includes peripheral circuitry optionally including row periphery write assist circuitry 102 and column periphery write assist circuitry 103.

Having separate Write and Read word lines in conjunction with the buffered, single-sided READ in the memory cell 105 essentially eliminates the risk of upset of data stored in the memory cell 105 when only the Read word line is turned ON. This allows optimization of the Read word line drive and of a read buffer in the memory cell 105 for performance in a READ cycle without concern for memory cell upset. This separation of Read and Write word lines also potentially allows optimization of the Write word line driver and of the memory elements 105 for the WRITE operation without concern for upset except for the half-selected cells in WRITE, as described below. However, the ability to READ without upset facilitates using a READ and WRITE-BACK for the half-selected cells in a WRITE cycle. Then, the Write word line driver and the memory element 105 may be optimized for WRITE. For example, a Write word line WWL may be driven to a higher voltage to turn ON a Write pass gate more strongly to write either of two states into the memory cell 105.

For the case of the SRAM array 101 employing interleaving of a word, a WRITE does not typically involve writing to every column in the row. However, the Write word line is turning ON the Write pass gate transistor in every 7T SRAM cell in that selected row. The possibility of upsetting unselected columns in the selected row due to the Write word line being turned ON strongly may necessitate a READ and WRITE-BACK for cells in the unaddressed columns while writing to the selected columns. Also, interleaving may also be accommodated through other architectural solutions besides READ and WRITE-BACK.

For example, an architecture may be employed to avoid upsets wherein all of the columns in a row are written. Alternatively, The Write bit lines may be held at mid-rail in unaddressed columns. Another approach for the single-sided WRITE is to maintain the relative strengths of the pass gate and pull-down transistors in the 7T SRAM cell to avoid upset of the cell in unaddressed columns, but to reduce the stability of the addressed column in order to facilitate the WRITE. This may be done by the write assist circuitry 102, 103 by lowering an array high supply voltage V_{DD} or raising an array low supply voltage V_{SS} of the addressed columns.

Optionally, the array low supply voltage V_{SS} may be employed by row and, the array high supply voltage V_{DD} may be employed by column. Then, for WRITE, the array high supply voltage V_{DD} is lowered for the selected columns and, the array low supply voltage V_{SS} is raised for the selected rows. In this way, the selected memory cells 100 will have both lowered array high supply voltage V_{DD} and raised array low supply voltage V_{SS} to enable WRITE while the “half-selected” memory cells 105 will have only one of the lowered or raised supply voltages applied. This provides an assistance to WRITE to selected memory cells 105 while reducing a possibility of upsetting unselected memory cells 100.

FIG. 1B provides a timing diagram 150 showing writing and reading a ONE and a ZERO for the SRAM array 101 of FIG. 1A. FIG. 1B provides an example of addressing the i^{th} row and the j^{th} column as well as showing an unaddressed k^{th} column. Of course, when a row is addressed (i.e., a word line is asserted by turning ON) there is concern about how unaddressed columns may be affected.

To execute a WRITE, assert the Write word line WWL(i) associated with the addressed i^{th} row and drive the voltage on the Write bit line WBL(j) associated with the j^{th} column for the addressed memory cells, as shown. It may be arbitrarily chosen as to whether a Word bit line is driven HIGH for a ONE and LOW for a ZERO, or vise versa. If not all cells on a selected Write word line are to be written, the Write bit lines associated with the unaddressed memory cells on the selected Write word line are also driven to a selected voltage designed to neither force the associated memory cell to a ONE or a ZERO. Generally, this will be some mid-rail voltage. If write assist circuitry is employed, such as lowering the array high supply voltage V_{DD} or raising the array low supply voltage V_{SS} to the selected memory cells 105 or overdriving of the selected Word bit lines, then the Write bit lines associated with the half-selected memory cells 105 may be less critical and may be held at a rail voltage or allowed to float (i.e., not driven) optionally after being precharged to a rail voltage.

To execute a READ, the Read bit line RBL(j) is precharged. Generally, the Read bit lines are precharged to a voltage level above the array low supply voltage V_{SS}, typically to a periphery voltage. The Read word line RWL(i) associated with the addressed i^{th} row is asserted, and a voltage on the Read bit line RBL(j) associated with the addressed memory cells is sensed. For a stored ONE, the associated precharged Read bit line RBL(j) remains HIGH. For a stored ZERO, the associated precharged Read bit line RBL(j) is pulled LOW. Of course, the assignment of the Read bit line (j) being HIGH for a ONE and LOW for a ZERO may be reversed, as noted before.

A means for sensing bit line voltage on the Read bit line RBL(j) is well known in the art and may range from a simple inverter to a differential sense amplifier wherein the bit line voltage is compared to a reference voltage. Correspondingly, a process of reading from and writing back to the memory array may also be employed to overcome memory upset issues for half-addressed in a write cycle, as noted before.

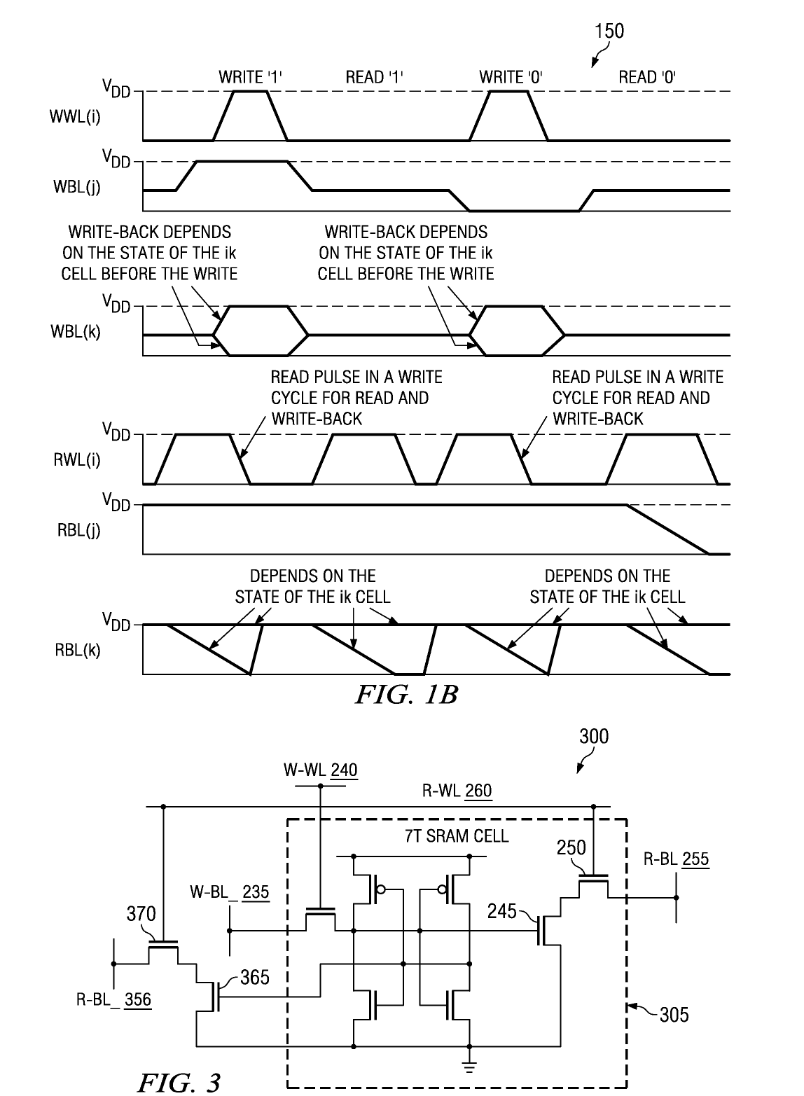

FIG. 2 illustrates an embodiment of a 7T SRAM cell 200 as may be employed in the SRAM array 100 of FIG. 1. The 7T SRAM cell 200 isolates READ and WRITE functions and thereby allows a balance between a robust SNM and robustness for providing a WRITE, which is proportional to the cell trip voltage Vₜᵣᵢₚ. Using separate pass gates for READ and WRITE allows separate optimization for SNM and trip voltage Vₜᵣᵢₚ. Additionally, isolating READ and WRITE functions allows a strong (i.e., relative high) read current I_{read} for an implementation footprint area, which itself is reduced over other configurations providing similar features. For example, transistors in a read buffer (such as a read buffer 207) may employ a lower threshold voltage than transistors in a memory element thereby allowing the strong read current I_{read} while maintaining memory element stability. Since fewer transistors are employed than current implementations (e.g., an 8T SRAM cell) to achieve the enhanced features, a lower value of leakage current I_{DDQ} thereby results, as well. Also, with one Write bit line compared to two Write bit lines of the 8T SRAM cell, the 7T SRAM cell will have lower dynamic power in a Write cycle.

The 7T SRAM cell 200 includes a memory element 205 employing a pair of cross-coupled inverters, connected to an array high supply voltage V_{DD}. The cross-coupled inverters have two storage nodes (node A and node B) and provide two stable states, one storage node HIGH and the other LOW, and vise-versa, to represent a single bit of information. The memory element 205 includes first and second n-type MOS pull-down transistors 210, 220 that are connected to corresponding first and second p-type MOS pull-up transistors 215, 225. An n-type MOS Read isolation transistor 245 is coupled to the memory element 205 wherein its gate 246 is connected to either node A or node B, as shown. Connecting to node A provides an opposite sense between Write and Read bit lines 235, 255. Correspondingly, connecting to node B provides a same sense between the Write and Read bit lines 235, 255. The Read isolation transistor 245 thereby provides a buffered Read output from the memory element 205 for either of the two states from one of the storage nodes of the cross-coupled inverters.

An n-type MOS Read pass gate transistor 250 is controlled by a Read word line 260 and connected between the Read isolation transistor 245 and the Read bit line 255 to read the buffered Read output. The Read pass gate transistor 250 provides either of the two states to the Read bit line 255 for the bit position. The single-sided READ is facilitated by the separation of I_{read} from SNM allowing a strong I_{read} with low threshold voltage V_{T} or short gate length and pull-down transistors and/or a boosted Read word line 260.

Since the READ is accomplished with the Read isolation transistor 245, which is a gain cell type circuit, the pull-down transistor (210 or 220 depending on whether node A or B is used) of the associated inverter does not need to be stronger than the Read pass gate transistor 250. Thus, the involved pull-down transistor may be made weaker or the Read pass gate transistor 250 stronger than for a standard 6T SRAM cell design. Additionally, the Read isolation and pass gate transistors 245, 250 may employ minimum gate lengths and lower threshold voltages for high READ current, which is especially advantageous for lower values of the array high supply voltage V_{DD}.

An n-type MOS Write pass gate transistor 230 is controlled by a Write word line 240 and connected between a junction of the first pull-down and pull-up transistors 210, 215 (i.e., a first transistor inverter junction in this example) and the Write bit line 235. Having a buffered READ capability allows the Write pass gate transistor 230 to be optimized for the single-sided WRITE. The single-sided WRITE requires that the Write pass gate 230 be strong enough (i.e., have enough conductivity and current capability) to pull against both the first pull-down and pull-up transistors 210, 215, when writing. Additionally, this allows the first pull-down and pull-up transistors 210, 215 to employ higher threshold voltage transistors with greater than minimum gate lengths as needed for stability.

The memory element 205 and the Write pass gate transistor 230 form a five transistor (5T) core 206 that provides a basic two-state memory for a bit position having a single-sided capability to WRITE either of the two states into the memory element 205. The buffered read capability may be added to either side of the memory element 205 in the 5T core 206 to form the 7T SRAM cell, as shown.

To execute a WRITE into the 7T SRAM cell 200, assert the Write word line 240 (i.e., drive it HIGH) and drive the Word bit line 235 either HIGH or LOW to force the state of the memory element 205. As mentioned before, the assignment of state for representation of a ONE or a ZERO is arbitrary. Possible assists to the WRITE are to lower the array high supply voltage V_{DD}, to raise the array low supply voltage V_{SS} (either separately or in combination) or to overdrive the selected Write bit lines.

To execute a READ from the 7T SRAM cell 200, precharge the Read bit line 255 to a voltage above the array low supply voltage V_{SS} and assert (i.e., drive HIGH) the Read word line 260. The Read buffer 207 (the Read isolation transistor 245 and the Read pass gate transistor 250) will either leave the Read bit line 255 floating HIGH or pull it toward the array low supply voltage V_{SS} depending on whether node A or node B is employed and the voltage value on the connected node. If node A is connected, data that is written with the Word bit line 235 HIGH will result in the Read bit line 255 being pulled toward the array low supply voltage V_{SS} in READ, and vise versa. If node B is connected, data that is written with the Word bit line 235 HIGH will result in the Read bit line 255 staying HIGH, and vice versa.

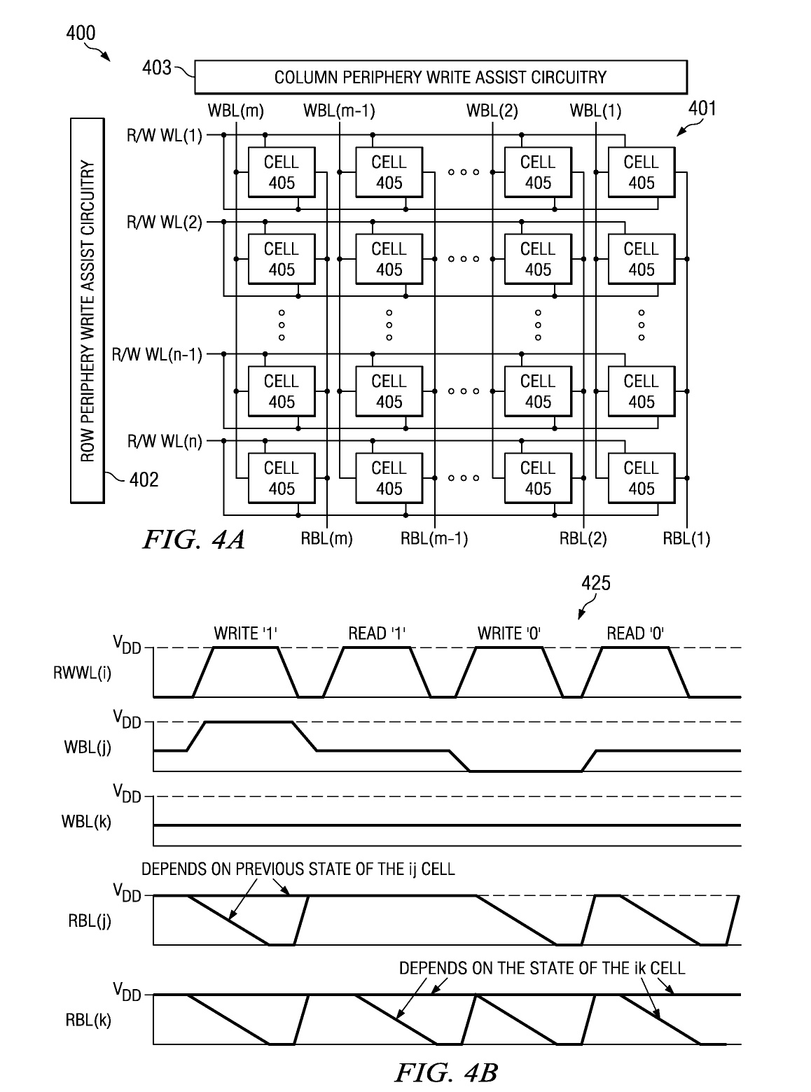

FIG. 3 illustrates an extension of one embodiment of the 7T SRAM cell of FIG. 2 to provide a 9T SRAM cell 300 having differential READ capability. The 9T SRAM cell 300 includes a 7T SRAM cell 305 having first Read isolation and Read pass gate transistors 245, 250 that are coupled to a first Read bit line 255, as employed in the 7T SRAM cell 200. The 9T SRAM cell 300 also includes second Read isolation and Read pass gate transistors 365, 370 that are coupled to a second Read bit line 356. Both the first and second Read pass gates 250, 370 are controlled by the Read word line 260, as shown.

Since the first and second Read bit lines 255, 356 are coupled to opposite storage nodes of the cross-coupled inverters in the memory element of the 7T SRAM cell, they thereby provide complementary read outputs corresponding to the differential READ capability. The Write bit line 235 and Write word line 240 still control what is written to the 9T SRAM cell 300. Additionally, the SRAM array 101 would have to incorporate a second Read bit line for each of the memory cells 105 to employ the 9T SRAM cell.

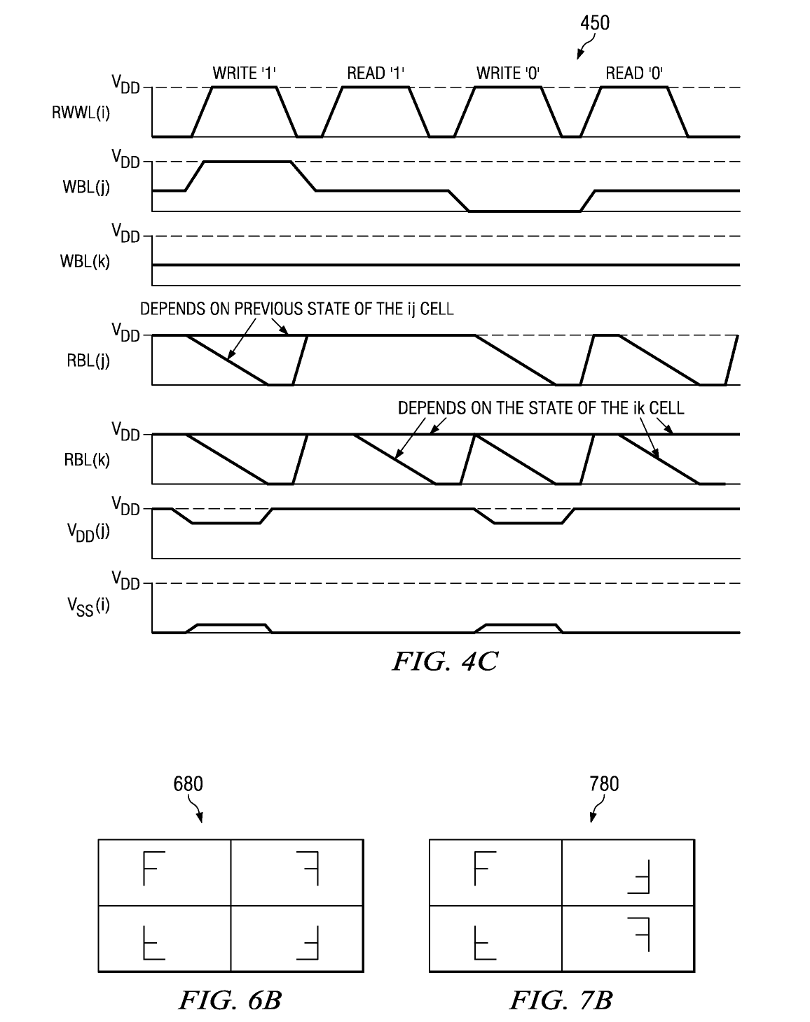

FIG. 4A illustrates an integrated circuit 400 including an SRAM array 401 as provided by an alternative embodiment of the disclosure. The SRAM array 401 includes a set of memory cells 405 wherein each cell is a 7T SRAM cell having a common Read/Write word line associated with each row of the memory cells 405. Additionally, single and separate Write and Read bit lines are still employed for each column of the memory cells 405.

The SRAM array 401 includes a plurality of common Read/Write word lines R/W WL(1)-R/W WL(n) associated with n rows of the memory cells 405. The SRAM array 401 also includes a plurality of Write bit lines WBL(1)-WBL(m) and a plurality of Read bit lines RBL(1)-RBL(m) associated with m columns of the memory cells 400. Each of the 7T SRAM cells employs the corresponding common Read/Write word line and Write bit line or Read bit line to provide a single-sided WRITE to or a buffered, single-sided READ from each of the memory cells 405. The integrated circuit 400 also includes peripheral circuitry optionally including row periphery write assist circuitry 402 and column periphery write assist circuitry 403.

FIG. 4B provides a timing diagram 425 showing writing and reading a ONE and a ZERO for the SRAM array 400 of FIG. 4A. The timing diagram 425 provides an example of addressing the i^{th} row and the j^{th} column as well as showing an unaddressed k^{th} column, as before. Also, when a row is addressed (i.e., a word line is asserted by turning ON) there is concern about how unaddressed columns may be affected.

To execute a WRITE in the SRAM array 400, assert the Read/Write word line RWWL(i) associated with the addressed i^{th} row and drive the voltage on the Write bit line WBL(j) associated with the j^{th} column for the addressed memory cells, as shown. As before, it may be arbitrarily chosen as to whether a Word bit line is driven HIGH for a ONE and LOW for a ZERO, or vise versa. If not all cells on a selected Write word line are to be written, the Write bit lines associated with the unaddressed memory cells on the selected Write word line are also driven to a selected voltage designed to neither force the associated memory cell to a ONE or a ZERO as may be seen for Write bit line WBL(k). Generally, this will be some mid-rail voltage, as shown. If write assist circuitry is employed, such as lowering the array high supply voltage V_{DD}, raising the array low supply voltage V_{SS} to the selected memory cells or overdriving of the selected Word bit lines, then the Write bit lines associated with the half-selected memory cells may be less critical and may be held at a rail voltage or allowed to float (i.e., not driven) optionally after being precharged to a rail voltage. Also, even with a common Read/Write word line, there can be some advantageous feedback from the Read bit line for the half-selected cells in a Write cycle.

To execute a READ, the Read bit line RBL(j) is precharged. Generally, the Read bit lines are precharged to a voltage level above the array low supply voltage V_{SS}, typically to a periphery voltage. The Read/Write word line R/WWL(i) associated with the addressed i^{th} row is asserted, and a voltage on the Read bit line RBL(j) associated with the addressed memory cells is sensed. For a stored ONE, the associated precharged Read bit line RBL(j) remains HIGH. For a stored ZERO, the associated precharged Read bit line RBL(j) is pulled LOW. Of course, the assignment of the Read bit line (j) being HIGH for a ONE and LOW for a zero may be reversed, as noted before.

As discussed before, a means for sensing bit line voltage on the Read bit line RBL(j) is well known in the art and may range from a simple inverter to a differential sense amplifier wherein the bit line voltage is compared to a reference voltage. Correspondingly, a process of reading from and writing back to the memory array may also be employed to overcome memory upset issues.

FIG. 4C provides an alternative timing diagram 450 where supply voltage write assist is employed for the SRAM array 400 of FIG. 4A. The timing diagram 450 provides two additional waveforms showing lowering the array high supply voltage V_{DD} for the j^{th} column and raising the array low supply voltage V_{SS} for the iₜₕ row when writing (either a ONE or a ZERO) to the SRAM array 400.

FIG. 4D provides yet another timing diagram 475 where overdrive of the Write bit line is employed for the SRAM array 400 of FIG. 4A. The timing diagram 475 shows a respectively higher voltage and lower voltage on the Write bit line WBL(j) when writing a ONE or a ZERO into the SRAM array 400, thereby providing the overdrive voltages.

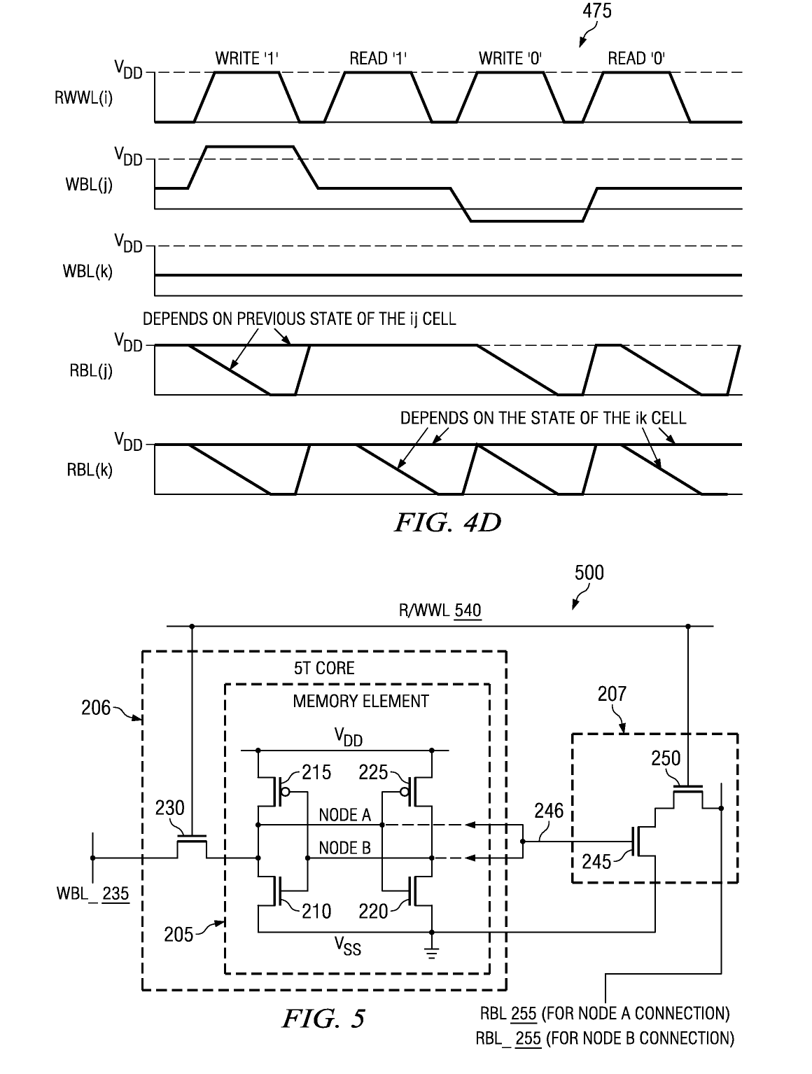

FIG. 5 illustrates an embodiment of a 7T SRAM cell 500 as may be employed in the SRAM array 400 of FIG. 4. The 7T SRAM cell 500 maintains the benefits afforded by the 7T SRAM cell 200 of FIG. 2, but combines the separate Write and Read word lines 240, 260 into a common Read/Write word line 540. The Read isolation transistor 245 may be connected to either node A or node B, as before.

To execute a WRITE into the 7T SRAM cell 500, assert the Read/Write word line 540 (i.e., drive HIGH) and also drive the word bit line 235 either HIGH or LOW to force a state of the memory element 205. Of course, the assignment of state for representation of a ONE or a ZERO is arbitrary, and the write assists and overdrive options discussed earlier may also be employed. With the common Read/Write word line 540, the read buffer 207 will drive the Read bit line 255 during WRITE just as in READ. However, the Read bit line does not need to be precharged in a WRITE cycle and may be left floating to conserve power.

To execute a READ, precharge the Read bit line 255 to a voltage above the array high supply voltage V_{DD} and assert (i.e., drive HIGH) the Read/Write word line 540. The read buffer 207 will either leave the Read bit line 255 floating HIGH or pull it toward the array low supply voltage V_{SS} depending on whether node A or node B is connected to the read buffer 207 and the voltage value on the connected node. If node A is connected, then data that is written with the Word bit line 235 HIGH will result in the Read bit line 255 being pulled toward the array low supply voltage V_{SS} in READ, and vise versa. If node B is connected, data that is written with the Word bit line 235 HIGH will result in the Read bit line 255 staying HIGH in READ, and vise versa.

With the common Read/Write word line 540, the write pass gate 230 will be turned ON during READ. This condition needs to be taken into account to avoid cell upsets on READ. This is analogous to the case of half-addressed memory cells on the addressed word line in WRITE, and similar precautions apply. The Write bit line 235 may be maintained at an intermediate voltage during READ to avoid writing either a ONE or a ZERO. Also, full voltage may be maintained across the memory element 205 during READ to avoid memory cell upsets and reduced for the selected cell to assist the write. Optionally, the Word line may not be turned ON as strongly (i.e., lower voltage) for a READ as for a WRITE. This further enables the option of READ and WRITE-BACK to the half-selected cells in a Write cycle.

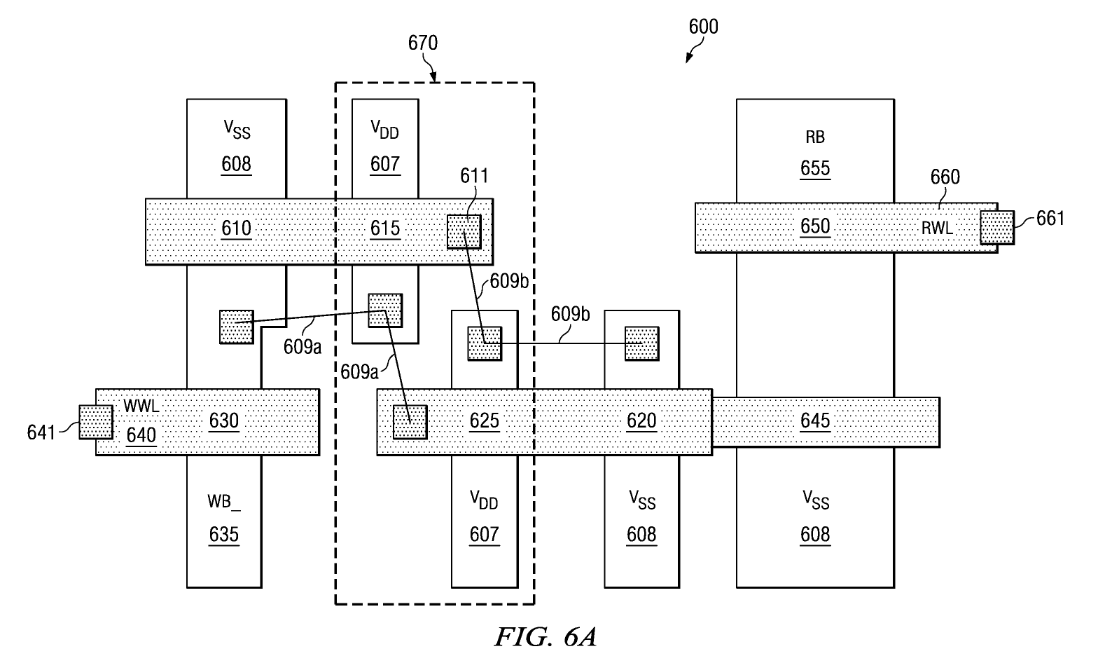

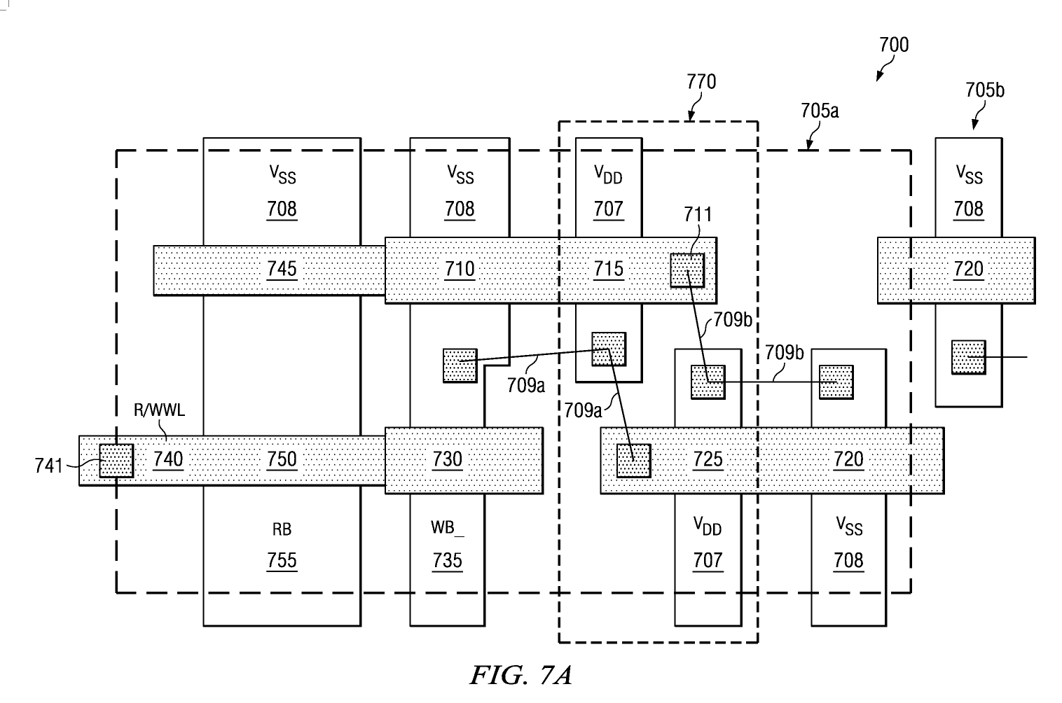

FIGS. 6A and 7A illustrate layout diagrams for constructing a 7T SRAM cell employing a p-type semiconductor substrate, as an example. For clarity, only the active and gate structures are shown along with a schematic indication of the interconnection of the inverters, in a physical layout representation. The layout of the bit lines, word lines and the power supply lines can follow standard procedures familiar to one skilled in the art of SRAM design.

FIG. 6A shows an example of a physical layout 600 of the 7T SRAM cell 200 of FIG. 2 for the connection represented by node A. In this embodiment, recall that separate Read and Write word lines are employed. The memory element 205 includes first and second cross-coupled CMOS inverters having first and second n-type MOS pull-down transistors 610, 620 that are connected to corresponding first and second p-type MOS pull-up transistors 615, 625. The first and second n-type MOS pull-down transistors 610, 620 are formed in and on the p-type substrate. The corresponding first and second p-type MOS pull-up transistors 615, 625 are formed in and on an n-well 670 contained in the p-type substrate.

Gates of the first pull-down and pull-up transistors 610, 615 have a common gate structure, meaning that they are coupled using a single strip of gate material (e.g., polysilicon). Similarly, gates of the second pull-down and pull-up transistors 620, 625 also have another common gate structure. Separate groups of interconnects 609a, 609b and vias (of which via 611 is typical) provide interconnecting and cross-connecting of the first and second CMOS inverters to form the memory element 206.

An n-type MOS Read isolation transistor 645 is formed in and on the p-type substrate and shares the common gate structure of the second pull-down and pull-up transistors 620, 625 thereby connecting it to node A as shown in FIG. 2. The read isolation transistor 645 is connected to an n-type MOS Read pass gate transistor 650, which is also formed in and on the p-type substrate. The Read pass gate transistor 650 connects the Read isolation transistor 645 to a Read bit line 655 under the control of a Read word line 660 connected to its gate. An n-type MOS Write pass gate transistor 630 is formed in and on the p-type substrate and is connected between the first pull-down and pull-up transistors 610, 615 and a Word bit line 635 under the control of a Write word line 640.

The Write word line 640 includes a Write word line contact 641 that is shared with a neighboring physical layout of the 7T SRAM cell 200. Correspondingly, the Read word line 660 includes a Read word line contact 661 that is shared with another neighboring physical layout of the 7T SRAM cell 200. An organization of these neighboring physical layouts will be further discussed with respect to FIG. 6B below.

The gate lengths of the Write pass gate transistor 630, the first pull-down and pull-up transistors 610, 615 and the second pull-down and pull-up transistors 620, 625 are shown to be substantially equal, in the illustrated embodiment. The gate lengths of the Read isolation and the Read pass gate transistors 645, 650 are shorter than the other transistors in the SRAM cell. Generally, shorter gate lengths provide faster transistor turn-on and longer gate lengths typically reduce variability from process variation or from random variations in channel doping thereby providing a trade-off for SRAM design.

The gate width of the first pull-down transistor 610 is significantly greater than the gate width of the Write pass gate transistor 630, which in turn is wider than the gate widths of the first and second pull-up transistors 615, 625. The gate width of the second pull-down transistor 620 is substantially equal to the gate width of the Write word line 640. Additionally, the gate widths of the Read isolation and Read pass gate transistors 645, 650 are significantly wider than the other transistors in the SRAM cell. Generally, wider gate widths provide greater maximum drive currents.

FIG. 6B shows an arrangement of neighboring physical layouts 680 on a substrate corresponding to the physical layout 600 for the 7T SRAM cell 200 of FIG. 2. As noted above, the Write word line contact 641 and the Read word line contact 661 are shared with neighboring physical layouts. FIG. 6B shows an orientation for sharing the Write and Read word line contacts 641, 661 wherein the array of memory cells are arranged to provide a mirroring of the physical layouts in both directions.

In FIG. 7A, an example of a physical layout 700 of the 7T SRAM cell 500 of FIG. 5 for the connection represented by node B. In FIG. 7A, the layout elements have been rearranged from the layout of FIG. 6A to accommodate a common Read/Write word line 740 and allow a partial overlap between adjacent SRAM cells 705a, 705b. Layout of the SRAM cell 705b has been rotated 180 degrees with respect to the layout of the SRAM cell 705a, as shown.

Analogously, the memory element 205 includes first and second cross-coupled CMOS inverters having first and second n-type MOS pull-down transistors 710, 720 that are connected to corresponding first and second p-type MOS pull-up transistors 715, 725. The first and second n-type MOS pull-down transistors 710, 720 are formed in and on the p-type substrate. The corresponding first and second p-type MOS pull-up transistors 715, 725 are formed in and on an n-well 770 contained in the p-type substrate.

Gates of the first pull-down and pull-up transistors 710, 715 have a common gate structure. Similarly, gates of the second pull-down and pull-up transistors 720, 725 also have another common gate structure. Again, separate groups of interconnects 709a, 709b and vias (via 711 being typical) provide interconnecting and cross-connecting of the first and second CMOS inverters to form the memory element 205.

An n-type MOS Read isolation transistor 745 is formed in and on the p-type substrate and shares the common gate structure of the first pull-down and pull-up transistors 710, 715 thereby connecting it to node B as shown in FIG. 5. The read isolation transistor 745 is connected to an n-type MOS Read pass gate transistor 750, which is also formed in and on the p-type substrate. The Read pass gate transistor 750 connects the Read isolation transistor 745 to a Read bit line 755 under the control of the common Read/Write word line 740 connected to its gate. An n-type MOS Write pass gate transistor 730 is formed in and on the p-type substrate and is connected between the first pull-down and pull-up transistors 710, 715 and a Word bit line 735 under the control of the common Read/Write word line 740. The Read/Write word line 740 includes a Read/Write word line contact 741 that is shared with a neighboring physical layout of the 7T SRAM cell 500.

The gate lengths of the Write pass gate transistor 730, the first pull-down and pull-up transistors 710, 715 and the second pull-down and pull-up transistors 720, 725 are shown to be substantially equal. The gate lengths of the Read isolation and the Read pass gate transistors 745, 750 are again shorter than the other transistors in the SRAM cell. As before, shorter gate lengths generally provide faster transistor turn-on and longer gate lengths typically reduce variability in SRAM implementation.

The gate width of the first pull-down transistor 710 is significantly greater that the gate width of the Write pass gate transistor 730, which in turn is wider than the gate widths of the first and second pull-up transistors 715, 725. The gate width of the second pull-down transistor 720 is substantially equal to the gate width of the Write pass gate transistor 730. Additionally, the gate widths of the Read isolation and Read pass gate transistors 745, 750 are significantly wider than the other transistors in the SRAM cell. Wider gate widths generally provide greater maximum drive currents. Note that in the configuration of FIG. 7A, the Read bit line and the Write bit line have the same sense. That is, data written with the Write bit line HIGH will result in the Read bit line staying HIGH when read, and vice-versa.

FIG. 7B shows an arrangement of neighboring physical layouts 780 on a substrate corresponding to the physical layout 700 for the 7T SRAM cell 500 of FIG. 5. As noted above, the Read/Write word line contact 741 is shared with neighboring physical layouts. FIG. 7B shows an orientation for sharing the Read/Write word line contacts 741 wherein the array of memory cells are arranged to provide a horizontal, 180 degree rotation and a vertical mirroring of the physical layouts.

Those skilled in the pertinent art will recognize that the gate lengths and widths depicted in FIGS. 6A and 7A may be designed to be different in other embodiments of the present disclosure. Additionally, relative positioning of the physical elements of the SRAM cells shown are examples of several possible embodiments that may be constructed according to the principles of the present disclosure.

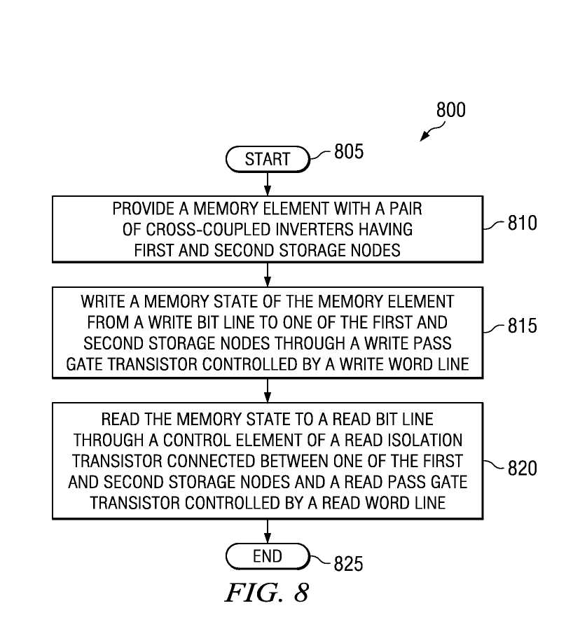

FIG. 8 shows a flow diagram of an embodiment of a method 800 of operating a 7T SRAM cell carried out according to the principles of the present disclosure. The method 800 starts in a step 805, and a memory element is provided with a pair of cross-coupled inverters having first and second storage nodes in a step 810.

Then, in a step 815, a memory state of the memory element is written from a Write bit line to one of the first and second storage nodes through a Write pass gate transistor controlled by a Write word line. In a step 825, the memory state is read to a Read bit line through a control element of a Read isolation transistor connected between one of the first and second storage nodes and a Read pass gate transistor controlled by a Read word line.

In the illustrated embodiment, each of the transistors is a MOSFET and the cross-coupled inverters are CMOS inverters. In one embodiment the Read isolation transistor and the Write pass gate transistor are connected to a same storage node of the cross-coupled inverters. In another embodiment, the Read isolation transistor and the Write pass gate transistor are connected to opposite storage nodes of the cross-coupled inverters. In still another embodiment, the Read word line and the Write word line are combined to form a common Read/Write word line. Generally, a drive current of the Write pass gate transistor is at least as great as the greater one of pull-up and pull-down drive currents corresponding to the one of the cross-coupled inverters. The method 800 ends in a step 825.

In summary, embodiments of the present disclosure employing a 7T SRAM cell employing both single-sided writing and buffered, single-sided reading capabilities have been presented. Advantages include mitigation of at least a portion of the problems associated with scaling to smaller geometries. The 7T SRAM cell employs a single-sided WRITE and a single-sided READ, wherein the single-sided READ uses a gain cell type output. In addition to providing a smaller footprint area than an 8T SRAM cell, this configuration maintains an adequate static noise margin (SNM) as well as provides robustness for WRITE (Vₜᵣᵢₚ), good read current capabilities (I_{read}) and low leakage current (I_{DDQ}).

Those skilled in the art to which the disclosure relates will appreciate that other and further additions, deletions, substitutions and modifications may be made to the described example embodiments without departing from the disclosure.

What is claimed is:

1. A seven transistor static random access memory (7T SRAM) cell, comprising:
a pair of cross-coupled inverters having first and second storage nodes;
a Read isolation transistor having a control element connected to one of the storage nodes of the cross-coupled inverters;
a Read pass gate transistor controlled by a Read word line and connected between the Read isolation transistor and a Read bit line; and
a Write pass gate transistor controlled by a Write word line and connected between one of the storage nodes of the cross-coupled inverters and a Write bit line.

2. The SRAM cell as recited in claim 1 wherein each of the transistors is a MOSFET and the cross-coupled inverters are CMOS inverters.

3. The SRAM cell as recited in claim 1 wherein the Read isolation transistor and the Write pass gate transistor are connected to a same storage node of the cross-coupled inverters.

4. The SRAM cell as recited in claim 1 wherein the Read isolation transistor and the Write pass gate transistor are connected to opposite storage nodes of the cross-coupled inverters.

5. The SRAM cell as recited in claim 1 wherein the Read word line and the Write word line are combined to form a common Read/Write word line.

6. The SRAM cell as recited in claim 1 wherein a drive current of the Write pass gate transistor is at least as great as the greater one of pull-up and pull-down drive currents corresponding to the one of the cross-coupled inverters.

7. An integrated circuit, comprising:
a Read word line and a Write word line corresponding to each row of a static random access memory (SRAM) array;
a Read bit line and a Write bit line corresponding to each column of the SRAM array; and
a seven transistor SRAM (7T SRAM) cell corresponding to a bit position at each intersecting row and column, including:
a pair of cross-coupled inverters having first and second storage nodes;
a Read isolation transistor having a control element that is connected to one of the storage nodes of the cross-coupled inverters;
a Read pass gate transistor that is controlled by the Read word line of the bit position and connected between the Read isolation transistor and the Read bit line of the bit position; and
a Write pass gate transistor that is controlled by the Write word line of the bit position and connected between one of the storage nodes of the cross-coupled inverters and the Write bit line of the bit position.

8. The integrated circuit as recited in claim 7 wherein each of the transistors is a MOSFET and the cross-coupled inverters are CMOS inverters.

9. The integrated circuit as recited in claim 7 wherein the Read isolation transistor and the Write pass gate transistor are connected to a same storage node of the cross-coupled inverters.

10. The integrated circuit as recited in claim 7 wherein the Read isolation transistor and the Write pass gate transistor are connected to opposite storage nodes of the cross-coupled inverters.

11. The integrated circuit as recited in claim 7 wherein the Read and Write word lines for each row of the SRAM array are combined to form a common Read/Write word line for the row.

12. The integrated circuit as recited in claim 7 wherein a physical layout includes adjacent pairs of 7T SRAM cells within a row having one of the cells in a pair rotated substantially 180 degrees with respect to the other cell of the pair.

13. The integrated circuit as recited in claim 12 wherein an adjacent pair of 7T SRAM cells within a row shares a common Read/Write word line contact.

14. The integrated circuit as recited in claim 7 wherein the Write pass gate transistor writes either of two states into one storage node of the cross-coupled inverters.

15. The integrated circuit recited in claim 7 wherein a drive current of the Write pass gate transistor is at least as great as the greater one of pull-up and pull-down drive currents corresponding to the one of the cross-coupled inverters.

16. The integrated circuit as recited in claim 7 wherein unselected bit positions in a selected row are read and then written-back while writing selected bit positions in the selected row.

17. The integrated circuit as recited in claim 7 further comprising a write assist circuit.

18. The integrated circuit as recited in claim 17 wherein the write assist circuit is operable to perform at least one selected from the group consisting of:
increase the Write word line voltage;
over drive the Write bit line voltage; and
lower a voltage across a selected cell.

19. The integrated circuit as recited in claim 7 wherein writing either of two states employs at least one selected from the group consisting of:
lowering a positive supply voltage of the SRAM array; and
raising a negative supply voltage of the SRAM array.

20. The integrated circuit as recited in claim 19 wherein the positive supply voltage is lowered for each selected column and the negative supply voltage is raised for a selected row.

21. The integrated circuit as recited in claim 7 wherein the Write bit line is held at substantially a mid-rail voltage value for unselected columns while writing to selected columns.

22. The integrated circuit as recited in claim 7 wherein a physical layout includes adjacent 7T SRAM cells that are mirror images of each other and provide a shared Read word line contact on one side and a shared Write word line contact on an opposite side of each 7T SRAM cell.

23. A nine transistor static random access memory (9T SRAM) cell, comprising:
a pair of cross-coupled inverters having first and second storage nodes;
a first Read isolation transistor having a control element connected to the first storage node;
a first Read pass gate transistor controlled by a Read word line and connected between the first Read isolation transistor and a first Read bit line;
a second Read isolation transistor having a control element connected to the second storage node;
a second Read pass gate transistor controlled by the Read bit line and connected between the second Read isolation transistor and a second Read bit line; and
a Write pass gate transistor controlled by a Write word line and connected between one of the first and second storage nodes and a Write bit line.

24. The SRAM cell as recited in claim 23 wherein the first and second Read bit lines provide a differential Read for the 9T SRAM cell.

25. The SRAM cell as recited in claim 23 wherein the Read word line and the Write word line are combined to form a common Read/Write word line for the 9T SRAM cell.

26. A method of operating a seven transistor SRAM (7T SRAM) cell, comprising:
providing a memory element with a pair of cross-coupled inverters having first and second storage nodes;
writing a memory state of the memory element from a Write bit line to one of the first and second storage nodes through a Write pass gate transistor controlled by a Write word line; and
reading the memory state to a Read bit line through a control element of a Read isolation transistor connected between one of the first and second storage nodes and a Read pass gate transistor controlled by a Read word line.

27. The method as recited in claim 26 wherein each of the transistors is a MOSFET and the cross-coupled inverters are CMOS inverters.

28. The method as recited in claim 26 wherein the Read isolation transistor and the Write pass gate transistor are connected to a same storage node of the cross-coupled inverters.

29. The method as recited in claim 26 wherein the Read isolation transistor and the Write pass gate transistor are connected to opposite storage nodes of the cross-coupled inverters.

30. The method as recited in claim 26 wherein the Read word line and the Write word line are combined to form a common Read/Write word line.

31. The method as recited in claim 26 wherein a drive current of the Write pass gate transistor is at least as great as the greater one of pull-up and pull-down drive currents corresponding to the one of the cross-coupled inverters.
